(19) United States
(12) Patent Application Publication
(10) Pub. No.: US 2026/0320244 A1
(43) Pub. Date: Oct. 15, 2026

(54) TREND HANDLING PROTOCOLS FOR DISTILLING TIME SERIES DATA

(71) Applicant: Asoka Jeevaka Maligaspe KORALE, Colombo (LK)

(72) Inventor: Asoka Jeevaka Maligaspe KORALE, Colombo (LK)

(21) Appl. No.: 19/179,860

(22) Filed: Apr. 15, 2025

(51) Int. Cl. G06F 30/20; G06F 18/241

(52) U.S. Cl. CPC G06F 30/20; G06F 18/241

(57) ABSTRACT

Protocols are described by which a first connective trend spanning first and second data states a second connective trend spanning second and third data states of a time series are obtained. Variabilities are obtained based on data states after said first data state for the first trend and after said third data state for the second trend. In some contexts the second trend may be adopted notwithstanding its larger variability, such as for manifesting insights gleaned from an action of a preference-conscious concierge or other expert. Alternatively or additionally such connective trends may be used in a novel data compression or a data distillation of the time series that preserves high precision.

### RELATED APPLICATIONS

None.

### BRIEF DESCRIPTION OF THE DRAWINGS

FIG. 1 depicts a system configured to extract, annotate, compare, or otherwise distill suitable connective trends in time series recordations in which one or more improved technologies may be incorporated.

FIG. 2 depicts a system configured to distill time series data collaboratively in which one or more improved technologies may be incorporated.

FIG. 3 depicts a time series of states related to one or more predictions in which one or more improved technologies may be incorporated.

FIG. 4 depicts a system in which time series data is handled across multiple remote facilities in which one or more improved technologies may be incorporated.

FIG. 5 depicts time series of precise points or other timestamped states and selectively related to one or more predictions in which one or more improved technologies may be incorporated.

FIG. 6 depicts another view of the time series of FIG. 5, one in which one or more predictions are obtained upon other selected bases, in which one or more improved technologies may be incorporated.

FIG. 7 depicts a scatter plot of a scalar component of (part of) another time series of states, some of which are associated with precise connective trends and predictions in which one or more improved technologies may be incorporated.

FIG. 8 depicts a system like that of FIG. 1 presenting a scatter plot of another time series of states suitable for display in a small image, some of which is associated with precise connective trends or predictions in which one or more improved technologies may be incorporated.

FIG. 9 depicts the system of FIG. 8 via which a user can further interact with the scatter plot so as to adjunct curved or straight connective trends in which one or more improved technologies may be incorporated to allow for space-efficient user controls.

FIG. 10 schematically depicts a server in which one or more improved technologies may be incorporated.

FIG. 11 schematically depicts a client device in which one or more improved technologies may be incorporated.

### DETAILED DESCRIPTION

The detailed description that follows is represented largely in terms of processes and symbolic representations of operations by conventional computer components, including a processor, memory storage devices for the processor, connected display devices, and input devices. Furthermore, some of these processes and operations may utilize conventional computer components in a heterogeneous distributed computing environment, including remote file servers, computer servers, and memory storage devices.

It is intended that the terminology used in the description presented below be interpreted in its broadest reasonable manner, even though it is being used in conjunction with a detailed description of certain example embodiments. Although certain terms may be emphasized below, any terminology intended to be interpreted in any restricted manner will be overtly and specifically defined as such.

The phrases “in one embodiment,” “in various embodiments,” “in some embodiments,” and the like are used repeatedly. Such phrases do not necessarily refer to the same embodiment. The terms “comprising,” “having,” and “including” are synonymous, unless the context dictates otherwise.

“Above,” “accurate,” “after,” “all,” “at least,” “authorized,” “automatic,” “based on,” “conditional,” “connected,” “contextual,” “corresponding,” “expected,” “first,” “justified,” “leading,” “more than,” “nonvolatile,” “numerous,” “partly,” “precise,” “predictive,” “presented,” “resulting,” “second,” “selective,” “single,” “some,” “spanning,” “tangible,” “wherein,” “with,” or other such descriptors herein are used in their normal yes-or-no sense, not merely as terms of degree, unless context dictates otherwise. In light of the present disclosure, those skilled in the art will understand from context what is meant by “remote” and by other such positional descriptors used herein.

Likewise, they will understand what is meant by “partly based” or other such descriptions of dependent computational variables/signals. “Numerous” as used herein refers to more than ten. “Immediate” as used herein refers to having a duration or delay of less than 5 minutes unless context dictates otherwise. Circuitry is “invoked” as used herein if it is called on to undergo voltage state transitions so that digital signals are transmitted therefrom or therethrough unless context dictates otherwise. Software is “invoked” as used herein if it is executed/triggered unless context dictates otherwise. Digital information is “obtained” as described herein by receiving it from a device user, by generating it or receiving it via various circuitry described herein, or by inferring it from a person who has apparently decided not to take an available action. One number is “on the order” of another if they differ by less than an order of magnitude (i.e., by less than a factor of ten) unless context dictates otherwise. As used herein “causing” is not limited to a proximate cause but also enabling, conjoining, or other actual causes of an event or phenomenon. “Instances” of an item may or may not be identical or similar to each other, as used herein.

Terms like “processor,” “center,” “unit,” “computer,” or other such descriptors herein are used in their normal sense, in reference to an inanimate structure. Such terms do not include any people, irrespective of their location or employment or other association with the thing described, unless context dictates otherwise. “For” is not used to articulate a mere intended purpose in phrases like “circuitry for” or “instruction for,” moreover, but is used normally, in descriptively identifying special purpose software or structures.

Reference is now made in detail to the description of the embodiments as illustrated in the drawings. While embodiments are described in connection with the drawings and related descriptions, there is no intent to limit the scope to the embodiments disclosed herein. On the contrary, the intent is to cover all alternatives, modifications and equivalents. In alternate embodiments, additional devices, or combinations of illustrated devices, may be added to, or combined, without limiting the scope to the embodiments disclosed herein.

In the interest of concision and according to standard usage in information management technologies, the functional attributes of modules described herein are set forth in natural language expressions. It will be understood by those skilled in the art that such expressions (functions or acts recited in English, e.g.) adequately describe structures identified below so that no undue experimentation will be required for their implementation. For example, any session metadata or other informational data identified herein may be represented digitally as a voltage configuration on one or more electrical nodes (conductive pads of an integrated circuit, e.g.) of an event-sequencing structure without any undue experimentation. Each electrical node is highly conductive, having a corresponding nominal voltage level that is spatially uniform generally throughout the node (within a device or local system as described herein, e.g.) at relevant times (at clock transitions, e.g.). Such nodes (lines on an integrated circuit or circuit board, e.g.) may each comprise a forked or other signal path adjacent one or more transistors. Moreover, many Boolean values (yes-or-no decisions, e.g.) may each be manifested as either a “low” or “high” voltage, for example, according to a complementary metal-oxide-semiconductor (CMOS), emitter-coupled logic (ECL), or other common semiconductor configuration protocol. In some contexts, for example, one skilled in the art will recognize an “electrical node set” as used herein in reference to one or more electrically conductive nodes upon which a voltage configuration (of one voltage at each node, for example, with each voltage characterized as either high or low) manifests a yes/no decision or other digital data.

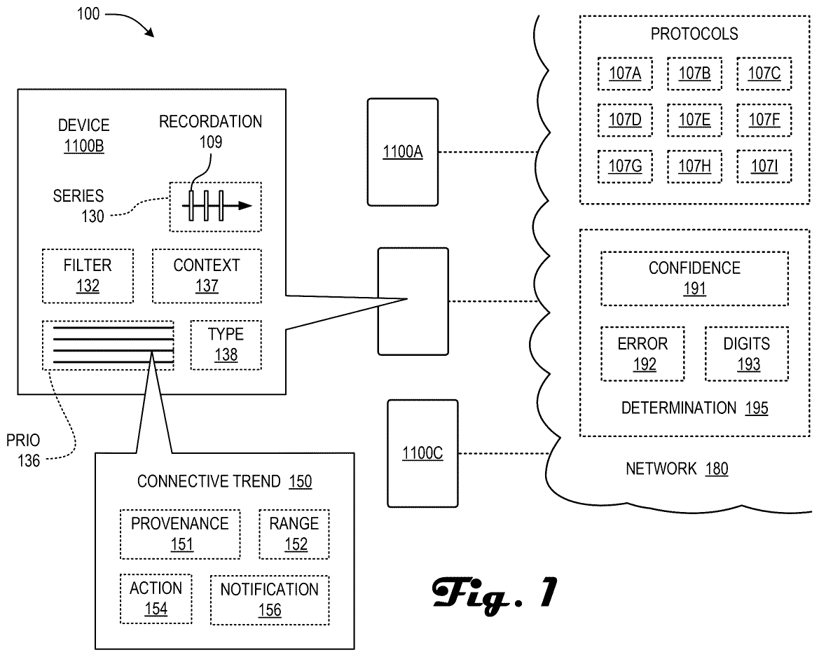

Referring now to FIG. 1, there is shown a system 100 configured to allow two or more client devices 1100A-C to interact via network 180 so as to allow selected points or other timestamped states in a recordation 109 of a time series 130 to be distilled into several candidate connective trends 150 that are expressed according to their respective prioritizations 136. With regard to each such trend 150 device 1100A may record associations with one or more instances of provenances 151, of ranges 152, of user actions 154 pertaining to the trend, or of justifications or other notifications 156. Moreover with regard to trend prioritization 136 device 1100A may record associations with one or more instances of data filters 132, of contexts 137, or of object types 138 (e.g. pertaining to risks or trend models). According to one or more network-resident or other digitally implemented protocols 107A-I, other aspects of user data and justification may include instances of levels of confidence 191, of explainable errors 192, of selected expressions of significant digits 193, or of other determinations 195 as further described below.

As used herein a trend is “connective” if it precisely spans two or more data points or other states of a time series. For a time series of N data states, for example, at most N−1 linear connective trends can include a given one of the states. Evaluating all of the N−1 options using a sum-of-squares or other user-preferred trend score allows them to be ranked in a user-preferred prioritization 136 or to be filtered so only a best-scoring 2-5 trends are initially presented to a user.

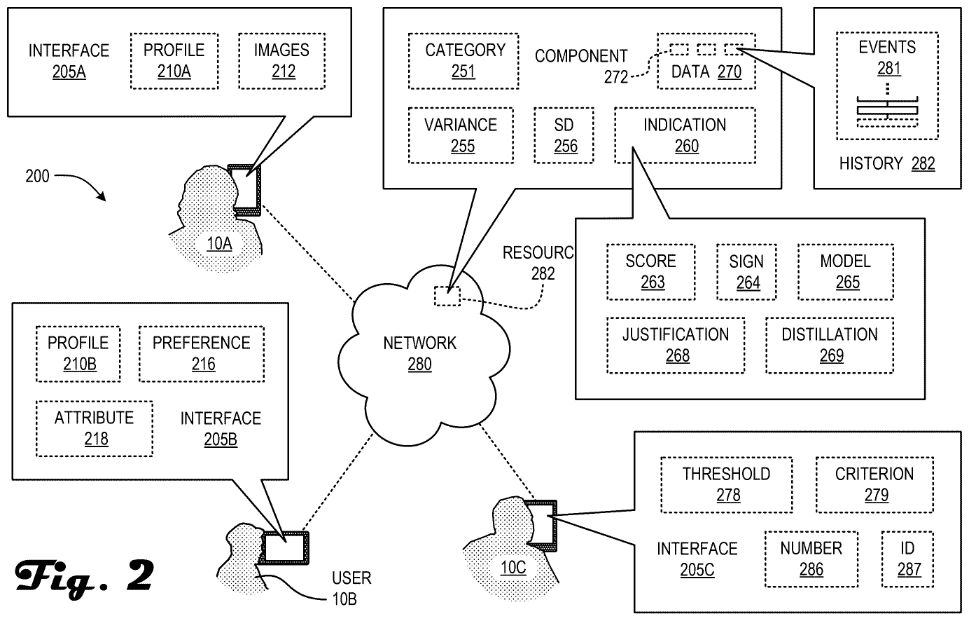

Referring now to FIG. 2, there is shown a system 200 configured to allow multiple users 10A-C to interact via one or more networks 280, optionally implementing one or more instances of system 100. In some contexts user 10A may provide a preference-indicative profile 210A and a time series 130 of states that comprise clip or move frames or other graphical images 213. Resources 282 of network 280 may likewise include or access a profile 210B of a second user 10B comprising explicit or other recognizable preferences 216, decisions, and other attributes 218 via a second interface 205B as shown. Alternatively or additionally network 280 may interact with a third user via a third interface 205C in regard to one or more of his thresholds 278 or other criteria 279, event counts or other numbers 286, or identifiers 287 herein.

Also described below are various network-accessible instances of categories 251, of variances 255 or standard deviations 256, or of other components 272 of tracked data 270. Other instances of scores 263, of signs 264, of models 265, of justifications 268, of distillations 269, or of other indications 260 may likewise be accessible via one or more networks 180, 280 in regard to sequences of events 281 in an annotated history 282 configured provide context 137 for explaining trends 150, anomalies, and related data items as described below.

As used herein a “justification” of a predicted value may include one or more precise operating parameters; a model or formula that defines a transfer function for converting the one or more parameters into the predicted value; a signature of an authorized user whose private key was used in selecting a non-default trend or value, or specific context about a prediction protocol 107F applied so as to assist an information provider in conveying a suitably complete meaning of the predicted value.

As used herein a predicted value is “justified” if one or more recipient-specified, standardized, or other authorized elements of its justification are simultaneously indicated with the predicted value. A notification recipient or cohort of users may establish a justification protocol 107C, for example, establishing what elements are required in a given context.

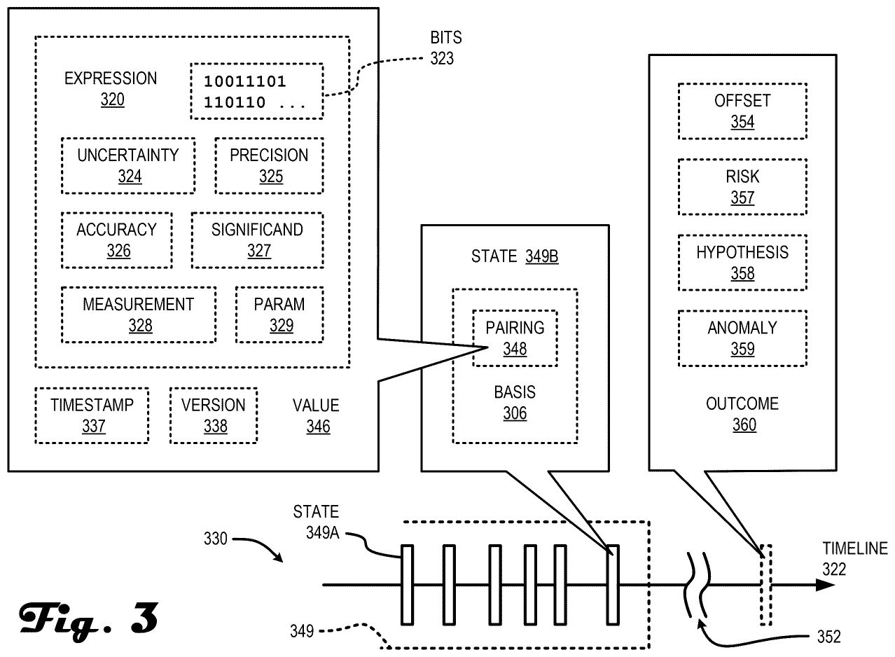

Referring now to FIG. 3, there is shown a time series 330 of numerous states 349 related to a predicted or actual outcome 360 (or both). Each of the numerous historical states 349 comprises a digital expression 320 having numerous bits 323 associated with a corresponding timestamp 337 within or pertaining to the time series 330. Each of the numerous states 349 may also indicate—expressly or otherwise—one or more instances of uncertainties 324, of precisions 325, of accuracies 326, of significands 327, of measurements 328 or other parameters 329, of versions 338, or of other values 346 within or pertaining to the time series 330. A segment of a time series 330 can then be characterized precisely by establishing (at least) a pairing 348 of states 349A-B (at least temporarily) deemed worthy as a basis 306 of a connective trend 150 therebetween.

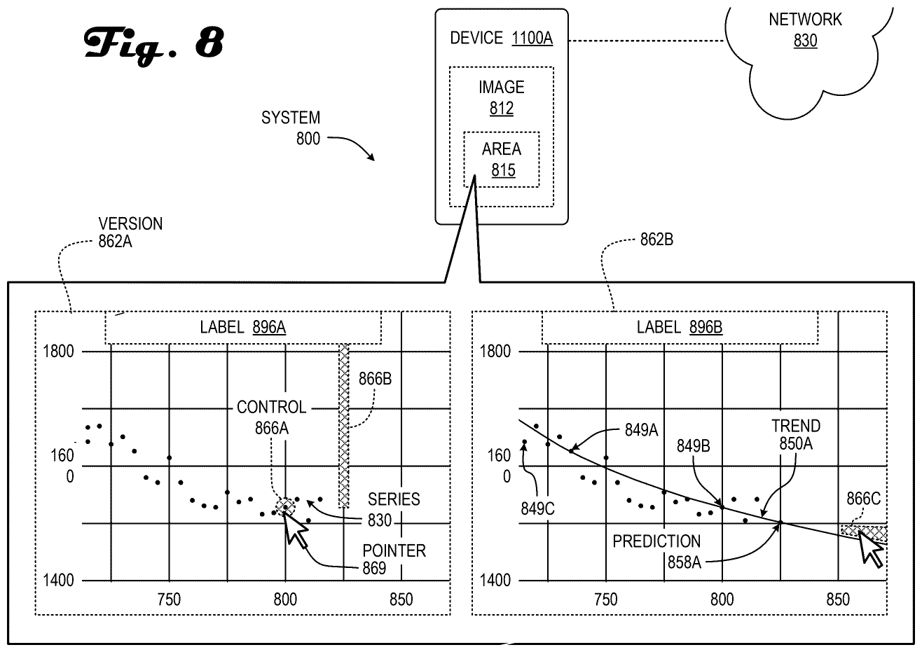

Based on one or more such trends 150 and a temporal offset 354 expressing a delay 352 along timeline 322 until an outcome 360 predicted by each of the one or more trends 150 pertains. Also within or associated with each such outcome 360 one or more features may be provided as expressions of risk 357 or of hypotheses 358 underlying the predicted outcome 360 (or both), some of which may characterize one or more outliers or other anomalies 359 relating to each trend 150. See FIG. 7.

Referring again to FIGS. 1-3, a first method herein comprises obtaining a time series 130, 330 that includes numerous vectors, pictographic images 213, or other data states 349 including first and second 349A-B. The method further comprises obtaining a first (digital expression 320 specifying a) first connective trend 150 spanning the first and second data states 349A-B of the time series 130, 330 and a corresponding first (“mild” risk type 138, trend score 263, or other) indications of risk 357 based on some or all of the numerous data states 349 that are after the first data state 349A. The method further comprises prioritizing one or more other connective trends 150 spanning respective pairings 348 of states 349 of the time series 130, 330 ranked below the first connective trend 150 based on their suboptimal indications of risk 357. Such indications 260 may include a percent of a (nominally) suboptimal trend relative to the first connective trend 150, for example, which can mitigate a predicted outcome 360 that is not based on the highest available trend scores 263 by providing a recipient with fair notice. Alternatively or additionally such indications 260 may justify the exception by identifying one or more users 10A-C who endorsed a selection of a suboptimal connective trend 150. This can occur, for example, in a context in which such users are aware of a physical or other knowable process (e.g. a growth rate) that casts doubt upon the first connective trend 150 or in which a user-selected connective trend 150 that spans curated states is preferable notwithstanding such higher indications of risk 357 (or both).

In some contexts in which historical high-precision states 349, 549 connected by trends to one another or other points have been significantly distilled (e.g. with a compression protocol 107E reducing their size by more than 10% for efficient transmission or storage), the resulting expression can be further distilled using a recipient-specific tailoring protocol 107A. A particular recipient, for example, may select or prefer an enriched presentation format with a sinusoidal, ramped, or other smooth interpolation between the high precision states 349, 549 or or smoothly extending from a newest historical state 349, 549 toward a predicted future value. Complex high quality states 349, 549 depicting high-res images 213, 813 or other snapshot-type data items (e.g. AI-enhanced depictions) may likewise undergo a selected or other favorable extension that places digital objects depicted in an estimated state (e.g. by incorporating a rotation, resizing, aging, morphing, simulation, or other projection technology) among or beyond the historical high precision states 349, 549 of the time series 130, 330 preserved as described herein. A suitable smoothing function may likewise be incorporated between a plateau-type presentation of each high-quality state so as to mitigate sawtooth-type or other abrupt transitions between presented trends. This can occur, for example, in a context in which more than half of the high-resolution or high-precision features (or both) of the connected high-quality states 349, 549 is preserved; in which such transitioning features an enhanced transition between high-quality states 349, 549; and in which a preserved high quality of such curated states 349, 549 would not be discernible to a recipient who views a distillation of the time series 130, 330 without such enhancement.

The first method further comprises responding to an authorized user action 154 signaling a preference 216 for another connective trend 150 over the first connective trend 150 notwithstanding the first connective trend 150 having less variability 459 than the first connective trend 150, 750A by (allowing or otherwise) obtaining a precise predictive outcome 360 based on an extrapolation of the user-selected connective trend 150. The precise predictive outcome 360 can be justified, for example, by an identifier of one or more authorized users who selected the new connective trend 150 over the first connective trend 150.

As used herein a scalar quantity is “precise” if it is canonical or if it primarily comprises or corresponds to one or more significands of at least 5 decimal digits. Approximate scalar components having fewer than 4 decimal digits are generally “imprecise.” As used herein a ratio, integer, or other quantity is “canonical” if it is deemed to have no uncertainty. A minute or day number in a uniform time series with regular time intervals is impliedly canonical, for example, unless it has decimal places or has been obtained by truncation or other approximation. As used herein an “uncertainty” of an argument, matrix element, measurement, estimate, deficit, computation, or other scalar quantity is any standard deviation or other probability-descriptive expression that represents a (uniform or other) statistical distribution of possible true values of the scalar quantity. See FIGS. 2-3.

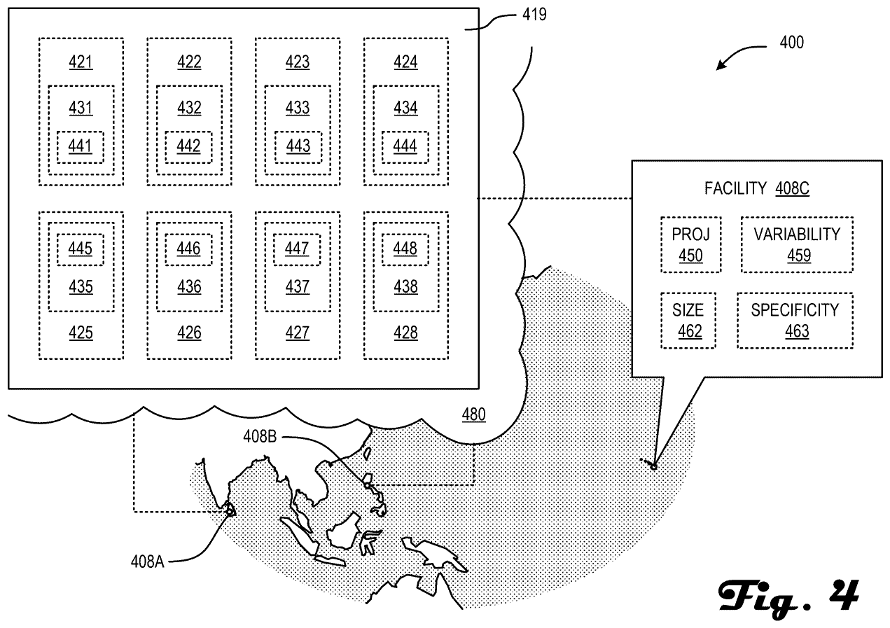

Referring now to FIG. 4, there is shown a system 400 by which interactions between a network 480 and a first facility 408A-B in Sri Lanka or Indonesia support handling time series data 270 on behalf of a remote second facility 408C in Hawaii or vice versa. Each such facility as shown interacts via cloud-based event-sequencing circuitry 419 in one or more networks 180, 280, 480 and via at least one remote facility (i.e. more than 100 kilometers away). Such circuitry 419 may comprise one or more integrated circuits (ICs), for example, optionally mounted on one or more circuit boards that implementing an event-sequencing structure as generally described in U.S. Pat. Pub. No. 2015/0094046 but configured as described herein. Transistor-based circuitry 419 may (optionally) include one or more instances of evaluation modules 421 configured for local or other processing, for example, (each) including an electrical node set 431 upon which informational data is represented digitally as a corresponding voltage configuration 441. Transistor-based circuitry 419 may likewise include one or more instances of interface modules 422 configured for local or other processing, for example, including an electrical node set 432 upon which informational data is represented digitally as a corresponding voltage configuration 442. Transistor-based circuitry 419 may likewise include one or more instances of response modules 423 configured for local or other processing, for example, including an electrical node set 433 upon which informational data is represented digitally as a corresponding voltage configuration 443. Transistor-based circuitry 419 may (optionally) likewise include one or more instances of invocation modules 424 configured for local or other processing, for example, including an electrical node set 434 upon which informational data is represented digitally as a corresponding voltage configuration 444. Transistor-based circuitry 419 may likewise include one or more instances of implementation modules 425 configured for local or other processing, for example, including an electrical node set 435 upon which informational data is represented digitally as a corresponding voltage configuration 445. Transistor-based circuitry 419 may likewise include one or more instances of distillation modules 426 configured for local or other processing, for example, including an electrical node set 436 upon which informational data is represented digitally as a corresponding voltage configuration 446. Transistor-based circuitry 419 may likewise include one or more instances of machine learning modules 427 configured for local or other processing, for example, including an electrical node set 437 upon which informational data is represented digitally as a corresponding voltage configuration 447. Transistor-based circuitry 419 may likewise include one or more instances of classification modules 428 configured for implementing, for example, including an electrical node set 438 upon which informational data is represented digitally as a corresponding voltage configuration 448.

In some contexts each facility 408 may specify one or more instances of interpolations or other projections 450, of variabilities 459, of digital object sizes 462, or of other descriptive features that establish a Boolean-valued specificity 463 of a state. Unless otherwise established by a facility 408 or authorized user 10 a state described herein is “specific” if it is larger than 500 bytes or if it includes a precise non-integer value with one or more decimal places (or both). And otherwise a state herein generally has no specificity 463 (e.g. a value of “false”).

As used herein such a context of a justification may comprise (1) an uncertainty of its most variable operand; (2) an explanation for an outlier in historical state data omitted from the predicted value; (3) a curved or other “type” of a model by which a precise prediction was obtained; (4) an accepted standard or other protocol version by which such a model was implemented; (5) a sampling rate, calibration offset, or other selected distillation parameter by which raw historical data was processed into a specific prediction; (6) an expression of a success of the model relative to one or more other models; (7) a comparative indicator of a competing predicted value; or (8) other user-specified elements of context 137 tending to justify a precision or specificity of the predicted value. As used herein a context is “specific” if it combines two or more of these eight elements.

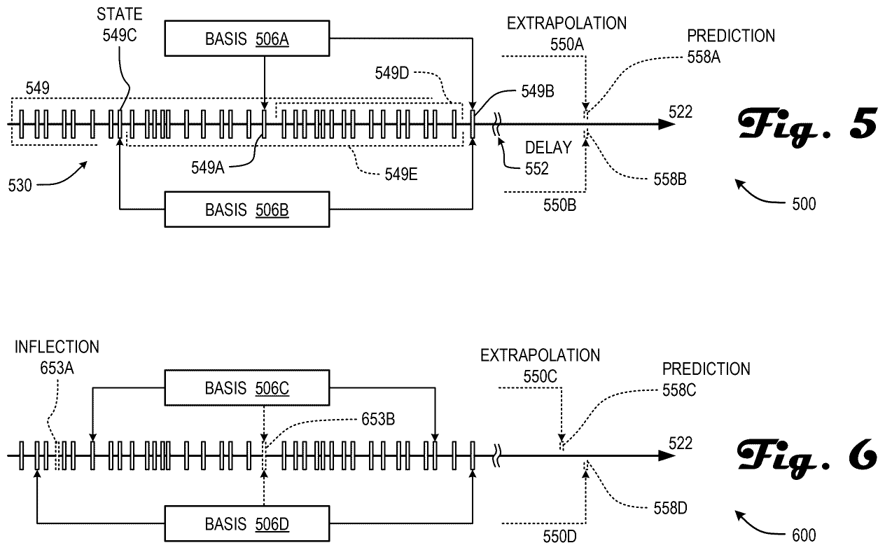

Referring now to FIG. 5, there is shown a schematic scatter plot 500 depicting a time series 530 of precise points or other timestamped historical states 549 along a timeline 522 and selectively related to one or more predictions 558A-B. Each of the historical states 549 comprises a digital expression 320 having numerous bits 323 associated with a corresponding timestamp 337 within or pertaining to the time series 530. Each of the numerous states 349 may also indicate a segment of time series 530 that can then be characterized precisely by establishing a basis 506A of two or more states 549A-B (at least temporarily) deemed worthy of a connective trend 150 therebetween. That basis 506A thereby supports a connective trend 150 that includes an interpolation spanning several additions states 549D and an extrapolation 550A that includes or leads to a precise prediction 558A. Another segment of time series 530 can be characterized precisely by establishing a basis 506B of two or more states 549B-C deemed worthy of a connective trend 150 therebetween. That basis 506B thereby supports a connective trend 150 that includes an interpolation spanning several additions states 549E and an extrapolation 550B that includes or leads to a precise prediction 558B as shown.

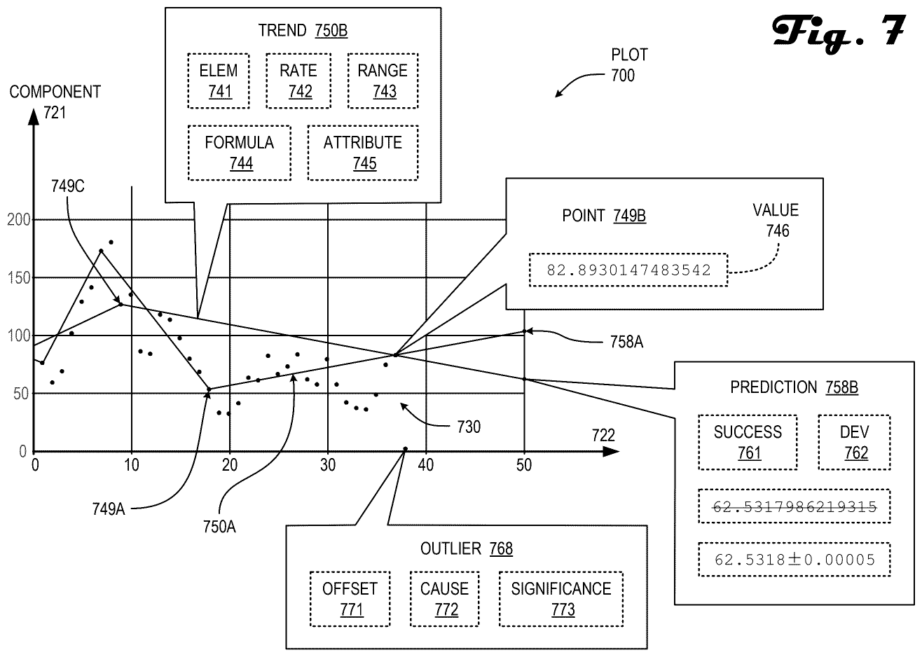

Referring now to FIG. 6, there is shown another schematic scatter plot 600 depicting time series 530 of timestamped historical states 549 along timeline 522 and selectively related to predictions 558C-D. Each of the historical states 549 comprises a digital expression 320 having numerous bits 323 associated with a corresponding timestamp 337 within or pertaining to the time series 530. Each of the numerous states 549 may also indicate a segment of time series 530 that can be characterized by establishing a basis 506C of two or more states 549A-B (at least temporarily) deemed worthy of a linear or other connective trend 150 therebetween. That basis 506C thereby supports one or more connective trends 150 that include an extrapolation 550C that includes or leads to a precise prediction 558C. Another segment of time series 530 can be characterized precisely by establishing a basis 506D of two or more states deemed worthy of one or more connective trends 150 therebetween and thereby supports an extrapolation 550D that includes or leads to a precise prediction 558D as shown. In some variants, moreover, a time series 530 may include an inflection as shown 653 (e.g. e.g. signifying a summit or thalweg). Moreover with anchor states on opposite ends of a basis 506C-D a suitable inflection 653B may be selected among the historical states that exhibits a smaller (sum-of-squares or other) variation than the others, an optimal joint between adjoining trends 150. See FIG. 7.

Referring now to FIG. 7, there is shown a scatter plot 700 of a time series 730 of states that include precise points 749 or other scalar components 721 at regular time intervals 213. The oldest of the depicted scalar components 721 is 76.5572360430464 at time 1. At time 18 the value of scalar component 721 is 53.7636096647026 (at a measured or computed “first” point 749A). At time 37 the value 746 of component 721 is 82.8930147483542 (at a “second” point 749B) as shown. At time 9 the precise value of scalar component 721 is 135.264973922918 (at a third point 749C). Spanning the first and second points 749A-B is an upward connective trend 750A as shown that justifies a precise increase prediction 758A. Spanning the second and third points 749B-C is a downward connective trend 750B that justifies a precise decrease prediction 758B. Although a computed prediction 758B is 62.5317986219315, this expression is unjustified insofar that it indicates a greater precision than is warranted by the respective uncertainties of the points 749B-C upon which it was based. A precise computed prediction 758B of 62.5318 (with an implied uncertainty of ±0.00005) is justified, however. A computed prediction is “justified” as used herein if (1) any user intervention in its derivation has a conspicuous manifestation and (2) its quantified variability is proportionally more conservative than that of its most variable determinant. Such manifestations may include an asterisk, explanation, sharp color difference, or other visual feature noticeable to a most users 10.

As described below each of these trends 750A-B may be described with reference to one or more instances of elements 741, of rate 742, of justifications 743, of formulas 744, or of other such trend-descriptive attributes 745 described herein.

Likewise each of these other predictions 758 may be described with reference to one or more instances of successes 761, of deviations 762, of justified or other predictive expressions, or of other such prediction-descriptive attributes described herein.

Likewise each outlier 768 or other component 721 in a time series 730 may be described with reference to one or more instances of offsets 771, of causes 772, of significance, or of other such state-descriptive attributes described herein.

Referring again to FIGS. 1-7, a second method herein comprises obtaining a time series 530, 730 that includes numerous scalar or other data states 549 including first, second, and third data states 549A-C (e.g. comprising points 749A-C). The second method further comprises obtaining a first (digital expression 320 specifying a) first connective trend 750A spanning the first and second data states 549A-B of the time series 530, 730 and a corresponding first (variance 255, standard deviation 256, or other) computed trend variability 459 based on some or all of the numerous data states 549 that are after the first data state 549A. The second method further comprises obtaining a second connective trend 750B spanning the second and third data states 549B-C of the time series 530, 730 and a corresponding second (trend score 263, standard deviation 256, or other) computed trend variability 459 (at least partly) based on some or all of the numerous data states 349, 549 that are after the third data state 349, 549C.

The second method further comprises obtaining a first (user selection 206, default 207, control activation 208, or other preference-indicative) user action 154 after (allowing or otherwise) causing the first and second connective trends 150, 750A-B to be (visually or otherwise) presented. The second method further comprises responding to the first user action 154 signaling a preference 216 for the second connective trend 150, 750B over the first connective trend 150, 750A notwithstanding the second connective trend 150, 750B having more variability 459 (e.g. “high” versus “medium” or having a higher variance or uncertainty) than the first connective trend 150, 750A by (allowing or otherwise) obtaining a precise predictive outcome 360 partly based on one or more user preference indications 260 and partly based on a first extrapolation 550 of the second connective trend 150, 750B.

In some variants the first or second method comprises implementing a compression protocol 107E of a time series 130, 330, 530, 730 in which several states 349, 549, 749 between each pairing 348 of basis states 349A-B, 549A-B are omitted in favor of (at least) a respective connective trend 150, 750 that spans that pairing 348 in which at least one connective trend 750C of the resulting distillation 269 is based upon a user action 154 upon a display of (at least part of) the time series 130, 330, 530, 730 and whereby a size (e.g. in kilobytes) of a resulting distillation 269 is reduced by more than 50% relative to the time series 130, 330 summarized by the resulting distillation 269.

Referring now to FIG. 8, there is shown a system 800 comprising a client device 1100A of FIG. 1 operably connected with one or more computation resources 282 or other entities 810 in or via one or more networks 180, 280, 480, 880. In some variants this allows real-time positions of pointers 869 of multiple users 10 to be shown simultaneously in a collaborative application image area 815 with respective user input(s) pertaining to one or more time series 130, 330, 530, 730 as described herein. In some contexts 137 one or more of the above-described trends 150, 750 are displayed among corresponding time series points 749 or other states 349, 549, 849 or other digital objects in a shared area 815 of an image 212, 812 acted upon by or presented to some or all of the users 10A-C in or via network 880.

In a preliminary version 862A of the image area 815, the newest several states 849 of time series 830 are shown. Each displayed state 849 is provided in a respective control 866A that allows one or more authorized users 10 to designate the state 849 as an outlier 768 and to select or enter a cause 772 as to its designation as such. Alternatively or additionally in some contexts 137 a preliminary default designation of such outliers may be obtained programmatically, for example by virtue of an excessive deviation from any recognized connective trend 850 among other states 849 of the time series 730. Moreover in some variants a user identification of a trend range 152 that does not include an outlier 768 also has an effect of removing an outlier 768 from consideration. A suitable justification 743 for such effects, for example, may include a human-visible expression such as an asterisk or highlighted label. Alternatively or additionally another control 866B can be maintained in the image area 815 by which a user 10 can trigger a pop-up menu or other presentation of an explanatory label 896A about the outlier 768 (e.g. “one-off anomaly not explained by any trend among other values in the series”). Alternatively or additionally in some variants a pivot point 749B may be designated as such by activation of its control 866A.

In response to such a designation, one or more connective trends 850 passing through the pivot state 849B are presented as shown. Moreover a later user input 1108 activating a prediction time designation control indicates one or more users 10 having a preference 216 for prediction at a specific future time 722 aligned with the control 866B at T=825. This may trigger one or more specific new respective predictions 858A to be generated and shown in a later image area version 862B partly based on a user-selected model 265 and partly based on a respective score 263 of several trends 850 generated by that model 265. As shown a leading logarithmic connective trend 850A precisely spans first and second states 849A-B and thereby justifies a precise prediction 858A as shown. Moreover an extended hovering or similar activation of control 866C may prompt a generation of one or more additional trends 858 precisely spanning anchor state 849B and a new paired state 849C as shown.

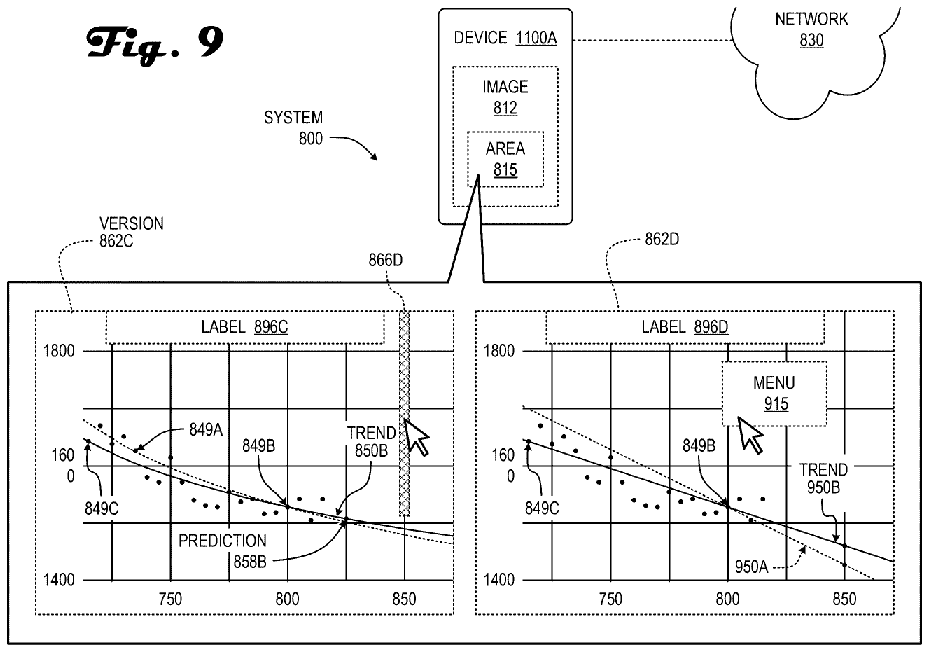

Such a preferred but apparently suboptimal trend 850B is shown in FIG. 9, which depicts a subsequent version 862C of image area 815 with a descriptive label 896C like “user requested secondary trend” or giving a precise prediction 858B at the user-requested time “T=825.” Another prediction 858 for preferred trend 850B at time T=850 may be provided instead in response to pointer 869 causing an activation of control 866D.

Referring now to version 862D, a menu 915 is activated that allows a user to select a “Linear” model in lieu of a “Logarithmic” model so that a best-scoring trend 950A through pivot state 849B is presented simultaneously with a user-preferred trend 950B, each indicated with its corresponding prediction at the user-selected time T=850 as shown.

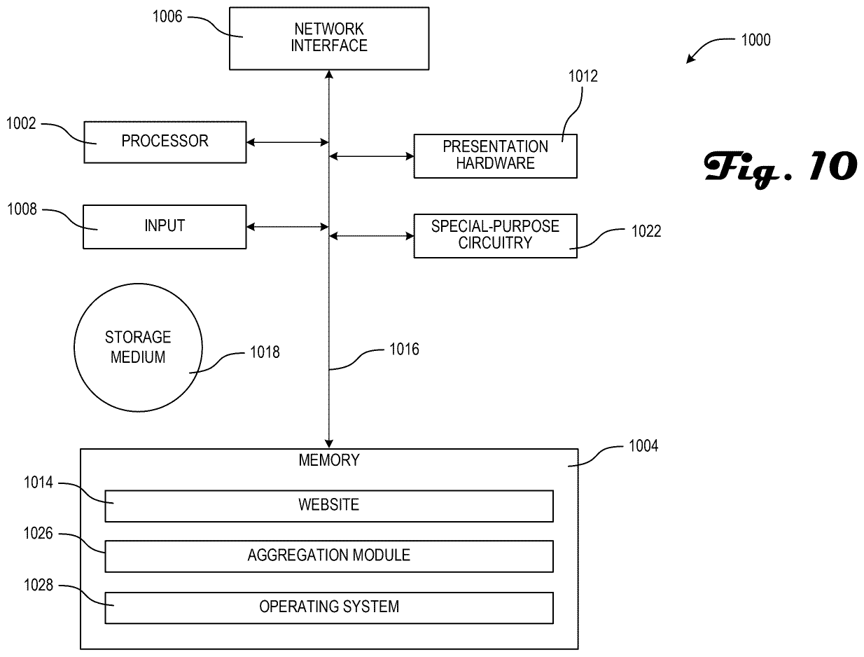

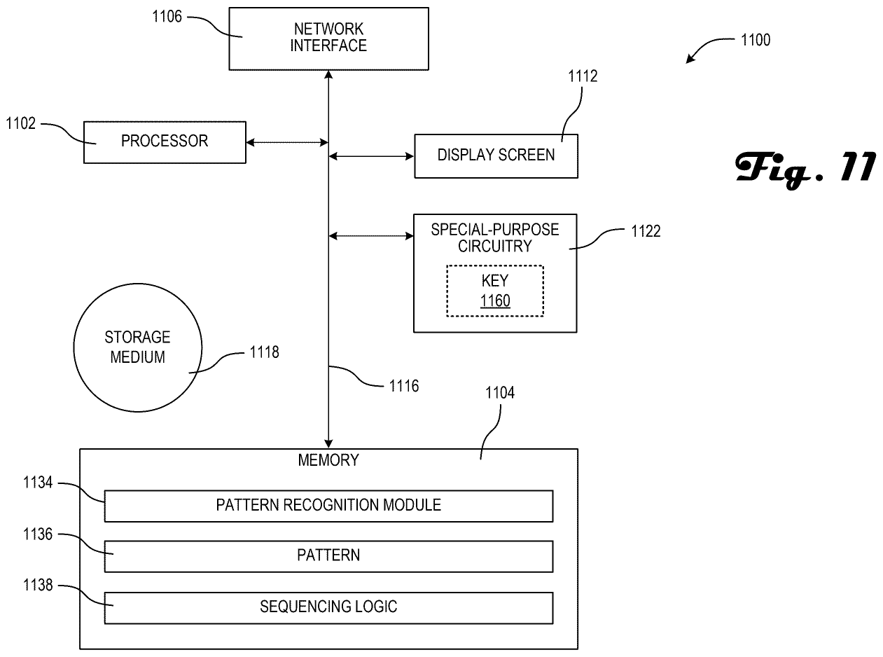

Referring now to FIG. 10, there is shown a server 1000 including one or more instances of processors 1002, of memories 1004, user inputs 1008, and of (speakers or other) presentation hardware 1012 all interconnected along with the network interface 1006 via a bus 1016. One or more network interfaces 1006 allow server 1000 to connect via the Internet or other networks 180, 280, 480, 880. Memory 1004 generally comprises a random access memory (“RAM”), a read only memory (“ROM”), and a permanent mass storage device, such as a disk drive.

Memory 1004 may contain one or more instances of websites 1014, of aggregation modules 1026, of operating systems 1028, or of data distillation modules that facilitate suggestions, confirmations, and feedback described herein. These and other software components may be loaded from a non-transitory computer readable storage medium 1018 into memory 1004 of the server 1000 using a drive mechanism (not shown) associated with a non-transitory computer readable storage medium 1018, such as a floppy disc, tape, DVD/CD-ROM drive, flash card, memory card, or the like. In some embodiments, software or other digital components may be loaded via the network interface 1006, rather than via a computer readable storage medium 1018.

Special-purpose circuitry 1022 may, in some variants, include some or all of the event-sequencing logic described herein. In some embodiments server 1000 may include many more components than those shown in FIG. 10, but it is not necessary that all conventional components of a server be shown in order to disclose an illustrative embodiment.

Referring now to FIG. 11, there is shown a client device 1100 in which one or more improved technologies may be incorporated. Client device 1100 may include one or more instances of processors 1102, of memories 1104, user inputs 1108, and of (speakers or other) presentation hardware 1112 all interconnected along with the network interface 1106 via a bus 1116. One or more network interfaces 1106 allow device 1100 to connect via the Internet or other networks 180, 280, 480, 880. Memory 1104 generally comprises a random-access memory (“RAM”), a read only memory (“ROM”), and a permanent mass storage device, such as a disk drive.

Memory 1104 may contain one or more instances of device-implemented pattern recognition modules 1134, of patterns 1136, or of other sequencing logic 1138 described herein. When implemented in device-executable code, these and other components may be loaded from a non-transitory computer readable storage medium 1118 into memory 1104 of the client device 1100 using a drive mechanism (not shown) associated with a non-transitory computer readable storage medium 1118, such as a floppy disc, tape, DVD/CD-ROM drive, flash card, memory card, or the like. In some embodiments, software or other digital components may be loaded via the network interface 1106, rather than via a computer readable storage medium 1118. Special-purpose circuitry 1122 (implementing a private key 1160 or other security feature, e.g.) may, in some variants, include some or all of the event-sequencing logic described herein. In some embodiments client device 1100 may include many more components than those shown in FIG. 11, but it is not necessary that all conventional components of a mobile device be shown in order to disclose an illustrative embodiment.

As used herein information being “provided” by artificial intelligence (“AI”) refers to expressions programmatically obtained on behalf of one or more users or user applications (1) by generative AI; (2) based on training data that relates to other people and partly based on one or more machine learning modules 427 applying elements of the training data 270 to a context of; or (3) based on one or more scores 263 described below. For example an “AI-provided” score 263 for a suggestion 240 may include . . . other such determinants described herein.

Although various operational flows are described in a sequence(s), it should be understood that the various operations may be performed in other orders than those which are illustrated or may be performed concurrently. Examples of such alternate orderings may include overlapping, interleaved, interrupted, reordered, incremental, preparatory, supplemental, simultaneous, reverse, or other variant orderings, unless context dictates otherwise. Furthermore, terms like “responsive to,” “related to,” or other past-tense adjectives are generally not intended to exclude such variants, unless context dictates otherwise.

While various system, method, article of manufacture, or other embodiments or aspects have been disclosed above, also, other combinations of embodiments or aspects will be apparent to those skilled in the art in view of the above disclosure. The various embodiments and aspects disclosed herein are for purposes of illustration and are not intended to be limiting herein. Definite articles herein are largely idiomatic or artifacts of translation and are not intended to be limiting except to the degree that they are recited in the final claim set.

In the numbered clauses below, first combinations of aspects and embodiments are articulated in a shorthand form such that (1) according to respective embodiments, for each instance in which a “component” or other such identifiers appear to be introduced (e.g., with “a” or “an,”) more than once in a given chain of clauses, such designations may either identify the same entity or distinct entities; and (2) what might be called “dependent” clauses below may or may not incorporate, in respective embodiments, the features of “independent” clauses to which they refer or other features described above.

### Clauses

Clause 1. A time series data distillation method comprising:
invoking transistor-based circuitry (e.g. one or more distillation or aggregation modules 426, 1026) configured to obtain a time series 130, 330, 530, 730, 830 comprising numerous (vector-valued or other) data states 349, 549 including first, second, and third data states 349, 549;
invoking transistor-based circuitry (e.g. a first evaluation module 421) configured to obtain a first (digital expression 320 specifying a) first connective trend 150, 750A spanning the first and second data states 349A-B, 549A-B of the time series 130, 330, 530, 730 and a corresponding first (“mild” risk type 138, confidence 191, trend score 263, variance 255, standard deviation 256, or other) computed trend variability 459 (at least partly) based on some or all of the numerous data states 349, 549 that are after the first data state 349A, 549A of the numerous data states 349, 549;
invoking transistor-based circuitry (e.g. a second instance of an evaluation module 421) configured to obtain a second connective trend 150, 750B spanning the second and third data states 549B-C of the time series 130, 330, 530, 730 and a corresponding second computed trend variability 459 (at least partly) based on some or all of the numerous data states 349, 549 that are after the third data state 349, 549C of the numerous data states 349, 549; and
invoking transistor-based circuitry (e.g. a first interface module 422) configured to obtain a first (user selection 206, default 207, control activation 208, or other preference-indicative) user action 154 after (allowing or otherwise) causing the first and second connective trends 150, 750A-B to be (visually or otherwise) presented (via a client device display screen 1112 or otherwise) to one or more users 10.
Clause 2. The method of any of the above clauses comprising:
invoking transistor-based circuitry (e.g. a first response module 423) configured to respond to the first user action 154 signaling a preference 216 for the second connective trend 150, 750B over the first connective trend 150, 750A notwithstanding the second connective trend 150, 750B having more variability 459 (e.g. “high” versus “medium” or having a higher variance or uncertainty) than the first connective trend 150, 750A by (allowing or otherwise) obtaining a precise predictive outcome 360 partly based on a second user action 154 indicating a (menu selection or display screen click position or other) preference indication 260 and partly based on a first (remotely generated or other) extrapolation 550 of the second connective trend 150, 750B.
Clause 3. The method of any of the above clauses comprising:
causing a computed uncertainty 324 corresponding to said second connective trend 150, 750 to be computed and displayed simultaneously with said second connective trend.
Clause 4. The method of any of the above clauses comprising:
causing first and second computed uncertainties 324 corresponding to said first and second connective trends 150, 750 to be computed and displayed simultaneously with said first and second trends 150, 750.
Clause 5. The method of any of the above clauses comprising:
automatically invoking transistor-based circuitry (e.g. a first invocation or implementation module 424-425) configured to cause the precise predictive outcome 360 to be presented (according to a justification protocol 107C via a client device display screen 1112 or otherwise) to a first user 10A of the one or more users 10 with one or more contextual justifications 268 of the second connective trend 150, 750B that comprise an alphanumeric identifier 266 of a model 265 by which the second connective trend 150, 750B was generated.
Clause 6. The method of any of the above clauses comprising:
implementing a compression protocol 107E of the time series 130, 330, 530, 730, 830 in which several states 349, 549, 749, 849 between each pairing 348 of basis states 349A-B are omitted in favor of a respective connective trend 150, 750, 850, 950 that spans that pairing 348 whereby a size 462 of a resulting distillation 269 is reduced by more than 50% relative to the time series 130, 330 summarized by the resulting distillation 269; and
transmitting the distillation 269 resulting from the compression protocol 107E to an archive or remote facility 408.
Clause 7. The method of any of the above clauses comprising:
implementing a compression protocol 107E of the time series 130, 330, 530, 730, 830 in which several states 349, 549, 749, 849 between each pairing 348 of basis states 349A-B are omitted in favor of a respective connective trend 150, 750, 850, 950 that spans that pairing 348 wherein at least one connective trend 750B of the resulting distillation 269 is based upon a user-selected (point 749C, 849 or other) state 349A and whereby a size 462 of a resulting distillation 269 is reduced by more than 20% relative to the time series 130, 330 summarized by the resulting distillation 269; and
transmitting the distillation 269 resulting from the compression protocol 107E to an archive or remote facility 408.
Clause 8. The method of any of the above clauses comprising:
implementing a compression protocol 107E of the time series 130, 330, 530, 730, 830 in which (at least) several states 349, 549, 749, 849 between each pairing 348 of basis states 349A-B are omitted in favor of a respective connective trend 150, 750, 850, 950 that spans that pairing 348 whereby a size 462 of a resulting distillation 269 is reduced by more than 50% relative to the time series 130, 330 summarized by the resulting distillation 269.
Clause 9. The method of any of the above clauses comprising:
implementing a compression protocol 107E of the time series 130, 330, 530, 730, 830 in which several states 349, 549, 749, 849 between each pairing 348 of basis states 349A-B are omitted in favor of a respective connective trend 150, 750, 850, 950 that spans that pairing 348 wherein at least one connective trend 750B of the resulting distillation 269 is based upon a user action 154 and whereby a size 462 of a resulting distillation 269 is reduced by more than 50% relative to the time series 130, 330 summarized by the resulting distillation 269; and
transmitting the resulting distillation 269 to an archive or remote facility 408.
Clause 10. The method of any of the above clauses comprising:
implementing a compression protocol 107E of the time series 130, 330, 530, 730, 830 in which several states 349, 549, 749, 849 between each pairing 348 of basis states 349A-B are omitted in favor of a respective connective trend 150, 750, 850, 950 that spans that pairing 348 wherein at least one connective trend 750B of the resulting distillation 269 is based upon a user action 154 upon a display of (at least part of) the time series 130, 330, 530, 730, 830 and whereby a size 462 of a resulting distillation 269 is reduced by more than 50% relative to the time series 130, 330 summarized by the resulting distillation 269; and
transmitting the distillation 269 resulting from the compression protocol 107E to an archive or remote facility 408.
Clause 11. The method of any of the above clauses comprising:
implementing a tailoring protocol 107A by causing one or more pattern recognition criteria 279 to be obtained for selective use on behalf of a first recipient that are not used on behalf of a second recipient.
Clause 12. The method of any of the above clauses comprising:
implementing a trending protocol 107H by causing one or more trend patterns to be applied that match one or more criteria 279 that are used selectively for a first destination context (e.g. a profile of one or more users in a destination cohort) but not for a second destination context.
Clause 13. The method of any of the above clauses comprising:
implementing a qualifying protocol 107D by obtaining a validation of two or more qualifying trends by allowing a local or other distillation module 426 to match one or more pattern recognition criteria 279 for a first destination context 137 (e.g. according to a profile 210A of one or more users in a first destination cohort) that are not used for a second destination context 137 (e.g. according to another profile 210B).
Clause 14. The method of any of the above clauses comprising:
implementing a compression protocol 107E by
causing a leading trend to be distinguished (with or without human guidance) from one or more other qualifying trends that match one or more pattern recognition criteria 279 that are used for a first destination context (e.g. a profile of one or more users in a destination cohort); and
automatically causing (a plurality of) justifications for using the leading trend in real time by differentiating the leading trend from (at least) another of the qualifying trends.
Clause 15. The method of any of the above clauses comprising:
recognizing an outlier 768 by one or more user-provided outlier recognition criteria 279 of a state categorization protocol 107B that include being a point 749 that differs from a preceding or next point 749 in the time series 730 by more than X % of a median magnitude of the other points 749 in the time series 730 wherein 1<X<20; and
excluding the outlier 768 from consideration when analyzing one or more trends 750, 850 in the time series 730.
Clause 16. The method of any of the above clauses wherein the second predictive outcome 360 comprises one or more connective trend formulas 304 or otherwise reflects a precise (constant or other) change rate 742.
Clause 17. The method of any of the above clauses wherein the second predictive outcome 360 is (at least partly) based on a precise first change rate 742.
Clause 18. The method of any of the above clauses wherein the first data state comprises a first precise point 749A at a first time (e.g. a first precise rate 742 of 53.7636096647026 at time 18), wherein the second data state comprises a second precise point 749B at a second time (e.g. a second precise rate 742 of 74.64541956 at time 36), and wherein the first connective trend 750A spanning the first and second data states of the time series 730 comprises a curvilinear model 265 by which a precise prediction for a third time is obtained.
Clause 19. The method of any of the above clauses wherein the first data state comprises a first accurate and precise point 749A at a first time (e.g. a first precise rate 742 of 53.7636096647026 at time 18), wherein the second data state comprises a second accurate and precise point 749B at a second time (e.g. a second precise rate 742 of 74.64541956 at time 36), and wherein the first connective trend 750A spanning the first and second data states of the time series 730 comprises a curvilinear model 265 by which a precise prediction for a third time is obtained.
Clause 20. The method of any of the above clauses wherein the first user 10A and a second user 10B respectively control two or more simultaneously-displayed pointers 869 via which input 1108 is received from each and wherein the second prediction 758B is partly based on input 1108 from the first user 10A and partly based on input 1108 from a second user 10B of the one or more users.
Clause 21. The method of any of the above clauses wherein a final second predictive outcome 360 is presented contemporaneously with a first variance 255 or other expression 320 of a risk 357 of the final second predictive outcome 360.
Clause 22. The method of any of the above clauses wherein a final second predictive outcome 360 is presented contemporaneously with a first precise expression 320 of a risk 357 of the final second predictive outcome 360.
Clause 23. The method of any of the above clauses wherein a final second predictive outcome 360 is defined as one or more selected connective trends 150, 750 reflects an extrapolated scalar prediction 558 partly based on a precise change rate 742 and partly based on a time interval 225 (e.g. a number 286 of hours or days after the last state 349B, 549B in the time series 130, 330, 530, 730, 830).
Clause 24. The method of any of the above clauses wherein a final second predictive outcome 360 is defined as one or more selected connective trends 150, 750 reflects an extrapolated scalar prediction 558 partly based on an accurate and precise change rate 742 and partly based on a time interval 225 (e.g. a number 286 of hours or days after the last state 349B, 549B in the time series 130, 330, 530, 730, 830).
Clause 25. The method of any of the above clauses wherein a final second predictive outcome 360 (defined as one or more computed or otherwise selected connective trends 150, 750) reflects an accurate and precise extrapolated scalar prediction 558.
Clause 26. The method of any of the above clauses wherein a scalar digital historical expression 320 has high accuracy 326 insofar that it differs from a corresponding true value 346, 746 only by one or more rounding or correctable errors 192 (e.g. needing calibration) of the scalar digital expression 320.
Clause 27. The method of any of the above clauses comprising:
using a value 346, 746 of an “outlier” category 251 as a trigger for an automatic explanation protocol 107G (at least partly) based on comparing a history 282 against a timestamp of a corresponding outlier 768.
Clause 28. The method of any of the above clauses comprising:
determining an expected range 303 (for a next interval) and automatically and conditionally notifying a user 10 in a real time mode 302 only a corresponding predicted value is outside the expected range 303.
Clause 29. The method of any of the above clauses wherein first and second predictive outcomes 360 of the second connective trend reflect a precise change rate 742 of a connective trend 150, 750 based on more than half of the states of the time series 130, 330, 530, 730 that are after the third data state 349C, 549C.
Clause 30. The method of any of the above clauses wherein the first and second predictive outcomes 360 reflect an accurate and precise extrapolated prediction 558 based on more than half of the data states after the third data state 549C.
Clause 31. The method of any of the above clauses comprising:
after causing a presentation of several sinusoidal, logarithmic, or other curved connective trends including a state prediction 758 of each simultaneously with a label 896B (e.g. including “logarithmic models” or “sinusoidal models”) describing the connective trends 750 to one or more users 10, receiving from (at least one of) the one or more users 10 a different model type preference 216 (e.g. via a selection of “basic” or “linear” on menu 897); and
responding to the different model type preference 216 by causing a presentation of several linear connective trends 750 including a state prediction 758 of each simultaneously with a superseding label 896B (e.g. “linear models”) describing the several linear connective trends 750 to the one or more users 10.
Clause 32. The method of any of the above clauses comprising:
receiving first user input 1108 identifying a model type 138 used in relation to the time series 130, 330, 530, 730;
receiving second user input 1108 identifying a specific future time 722 relative to the time series 130, 330, 530, 730; and
generating the first and second trends 758 partly based on the first and second user inputs 1108 and partly based on the specific future time 722.
Clause 33. The method of any of the above clauses comprising:
providing an explanatory label 896A about an outlier 768 among the time series 130, 330, 530, 730 (e.g. “attributed to a transmission error”) that was previously inserted by an authorized user and that justifies the second connective trend 150, 750B in response to the user input identifying the outlier 768.
Clause 34. The method of any of the above clauses comprising:
receiving user input 1108 identifying an outlier 768 among the time series 130, 330, 530, 730; and
presenting an explanatory label 896A about an outlier 768 among the time series 130, 330, 530, 730 (e.g. “attributed to a transmission error”) that was previously inserted by an authorized user and that justifies the second connective trend 150, 750B in response to the user input identifying the outlier 768.
Clause 35. The method of any of the above clauses comprising:
signifying an eligible model 265 in one or more other points after time 18 are outliers 768 or otherwise deemed less reliable than “anchor” point 749B. This can occur, for example, in a context 137 in which another point 749A and the anchor point 749B each have at least X>6 digits of precision 325, in which these values 746 are combined with a linear model 265 or other explicit formula 744 to form a connective trend 750A between them that is overt enough that a prediction 758A of that posited trend 750A also supports a high precision 325 (e.g. six digits).
Clause 36. The method of any of the above clauses comprising:
after causing a presentation of a (curved or other) nonlinear connective trend including a state prediction 758 thereof simultaneously with a label 896B (e.g. including “logarithmic models” or “nonlinear models”) describing the nonlinear connective trends 750 to one or more users 10, receiving from (at least one of) the one or more users 10 a different model type preference 216 (e.g. via a selection of “linear” on menu 897); and
responding to the different model type preference 216 by causing a presentation of a linear connective trends 750 including a state prediction 758A-C of each simultaneously with a superseding label 896B (e.g. “linear models”) describing the several linear connective trends 750 to the one or more users 10.
Clause 37. The method of any of the above clauses comprising:
after causing a presentation of several curved connective trends including a state prediction 758 of each simultaneously with a label 896B (e.g. including “logarithmic models” or “sinusoidal models”) describing the connective trends 750 to one or more users 10, receiving from (at least one of) the one or more users 10 a different model type preference 216 (e.g. via a selection of “basic” on menu 897); and
responding to the different model type preference 216 by causing a presentation of several linear connective trends 750 including a state prediction 758A-C of each simultaneously with a superseding label 896B (e.g. “linear models”) describing the several linear connective trends 750 to the one or more users 10.
Clause 38. The method of any of the above clauses comprising:
assigning to the second state 349B, 549B a value 346, 746 that is associated with a precise time 722 and is specific (at least) by virtue of including an alphanumeric or other recordation 109 larger than 500 bits.
Clause 39. The method of any of the above clauses comprising:
assigning to the second state 349B, 549B a value 346, 746 that is specific by virtue of including an alphanumeric or other recordation 109 larger than 1000 bits.
Clause 40. The method of any of the above clauses comprising:
assigning to the second state 349B, 549B a value 346, 746 that is specific (at least) by virtue of including two or more geographic coordinates.
Clause 41. The method of any of the above clauses comprising:
assigning to the second state 349B, 549B a location-specific value 346, 746 that is specific by virtue of including three or more positional coordinates.
Clause 42. The method of any of the above clauses comprising:
associating the second state with a historic event that has a value 346, 746 that is “specific” by virtue of associating an alphanumeric identifier 287 therein with a scalar measurement having an uncertainty 324 smaller than 0.5% thereof.
Clause 43. The method of any of the above clauses comprising:
associating the second state with a point 749B that has a scalar component value 346, 746 that is specific (at least) by virtue of corresponding to a significand 327 of more than 3 decimal digits associated with an alphanumeric identifier 287 therein (e.g. “cc”).
Clause 44. The method of any of the above clauses comprising:
associating the second state with a point 749B that has a scalar component value 346, 746 that is “specific” (at least) by virtue of corresponding to a significand 327 of more than 4 decimal digits associated with a unit identifier (e.g. “○”) therein.
wherein the second state comprises a point 749B that has a component value 346, that is “specific” by virtue of corresponding to a significand 327 of more than 4 (decimal) digits.
Clause 45. The method of any of the above clauses comprising:
associating the first and second data states 349A-B, 549A-B with corresponding precise change rates 742.
Clause 46. The method of any of the above clauses comprising:
associating the data states 349, 549 each to a single vector value 346 or to a precise scalar value 346.
Clause 47. The method of any of the above clauses comprising:
associating the first and second data states 349A-B, 549A-B each with a 2×2 or larger matrix value 346 or a precise scalar value 346 (or both).
Clause 48. The method of any of the above clauses comprising:
associating the first and second data states 349A-B, 549A-B each with a precise scalar value 346 having more than 8 digits.
Clause 49. The method of any of the above clauses comprising:
associating the first and second data states 349A-B, 549A-B each with a precise scalar value 346 having more than 10 digits.
Clause 50. The method of any of the above clauses comprising:
associating the first and second data states 349A-B, 549A-B each with a respective floating-point value 346 in a corresponding digital record 109.
Clause 51. The method of any of the above clauses comprising:
associating the first and second data states 349A-B, 549A-B each with a single clip frame (e.g. of an animation) or a precise scalar value 346.
Clause 52. The method of any of the above clauses comprising:
associating the first and second data states 349A-B, 549A-B each with one or more photographic images 212, 812 that each include multiple precise scalar values 346 (e.g. as a fine grayscale level or pixel color).
Clause 53. The method of any of the above clauses 1 comprising:
associating the first and second data states 349A-B, 549A-B each with one or more network traffic states pertaining to a single network node.
Clause 54. A time series data distillation system 100, 200, 400, 800 comprising:
the transistor-based circuitry of any one of the above method clauses.
Clause 55. A time series data distillation system comprising:
transistor-based circuitry (e.g. one or more distillation or aggregation modules 426, 1026) configured to obtain a time series 130, 330, 530, 730, 830 comprising numerous (scalar or other) data states 349, 549 including first, second, and third specific data states 349, 549;
transistor-based circuitry (e.g. a first evaluation module 421) configured to obtain a first (digital expression 320 specifying a) first connective trend 150, 750A spanning the first and second data states 349A-B, 549A-B of the time series 130, 330, 530, 730 and a corresponding first (“mild” risk type 138, confidence 191, trend score 263, variance 255, standard deviation 256, or other) computed trend variability 459 (at least partly) based on some or all of the numerous data states 349, 549 that are after the first data state 349A, 549A of the numerous data states 349, 549;
transistor-based circuitry (e.g. a second instance of an evaluation module 421) configured to obtain a second connective trend 150, 750B spanning the second and third data states 549B-C of the time series 130, 330, 530, 730 and a corresponding second computed trend variability 459 (at least partly) based on some or all of the numerous data states 349, 549 that are after the third data state 549C of the numerous data states 349, 549; and
transistor-based circuitry (e.g. a first interface module 422) configured to obtain a first (user selection 206, default 207, control activation 208, or other preference-indicative) user action 154 after (allowing or otherwise) causing the first and second connective trends 150, 750A-B to be (visually or otherwise) presented (via a client device display screen 1112 or otherwise) to one or more users 10.

The system of any of the above system clauses configured to include most or all numbered features of system 100 as shown in FIG. 1.

The system of any of the above system clauses configured to include most or all numbered features of system 200 as shown in FIG. 2.

The system of any of the above system clauses configured to include most or all numbered features of system 400 as shown in FIG. 4.

The system of any of the above system clauses configured to include most or all numbered features of system 800 as shown in FIG. 8.

The computing system of any of the above system clauses wherein an instance of invocation and interface logic thereof (is included and) resides on a single integrated circuit chip.

The computing system of any of the above system clauses wherein an instance of invocation and interface logic thereof resides in a single apparatus.

The computing system of any of the above system clauses wherein an instance of invocation and interface logic thereof (is included and) resides in one or more cloud-resident servers 500.

The computing system of any of the above system clauses and configured to perform a method of any one of the above method clauses.

With respect to the numbered claims expressed below, those skilled in the art will appreciate that recited operations therein may generally be performed in any order. Also, although various operational flows are presented in sequence(s), it should be understood that the various operations may be performed in other orders than those which are illustrated or may be performed concurrently. Examples of such alternate orderings may include overlapping, interleaved, interrupted, reordered, incremental, preparatory, supplemental, simultaneous, reverse, or other variant orderings, unless context dictates otherwise. Terms like “responsive to,” “related to,” or other such transitive, relational, or other connections do not generally exclude such variants, unless context dictates otherwise. Furthermore each claim below is intended to be given its least-restrictive interpretation that is reasonable to one skilled in the art.

What is claimed is:

1. A time series data distillation method comprising:
invoking first transistor-based circuitry configured to obtain a time series comprising numerous data states including first, second, and third specific data states;
invoking second transistor-based circuitry configured to obtain a first connective trend spanning said first and second data states of said time series and a corresponding first computed risk-indicative trend variability based on some or all of said numerous data states that are after said first data state of said numerous data states;
invoking third transistor-based circuitry configured to obtain a second connective trend spanning said specific second and third data states of said time series and a corresponding second computed trend variability based on some or all of said numerous data states that are after said third data state of said numerous data states;
invoking fourth transistor-based circuitry configured to obtain a first user action after causing said first and second connective trends and said respectively corresponding first and second computed uncertainties all to be presented simultaneously to one or more users; and
automatically invoking fifth transistor-based circuitry configured to respond to said first user action signaling a preference for said second connective trend over said first connective trend notwithstanding said second connective trend having more variability than said first connective trend by obtaining a precise first predictive outcome partly based on a second user action signaling a preference indication and partly based on a first extrapolation of said second connective trend.

2. The time series data distillation method of claim 1
automatically invoking sixth transistor-based circuitry configured to cause said precise first predictive outcome to be presented to a first user of said one or more users with one or more contextual justifications of said second connective trend that comprise an alphanumeric identifier of a model by which said second connective trend was generated.

3. The time series data distillation method of claim 1 comprising:
implementing a compression protocol of said time series wherein several of said numerous data states between a pairing of said numerous data states that includes said second specific data state are omitted from a first distillation of said time series in favor of a respective third connective trend that spans said pairing of said numerous data states wherein at least one connective trend of said first distillation is based upon a user action and whereby a size of said first distillation is reduced by more than 20% relative to said time series summarized by said resulting distillation; and
transmitting said first distillation to an archive or remote facility.

4. The time series data distillation method of claim 1 comprising:
implementing a qualifying protocol by obtaining a validation of two or more qualifying connective trends by allowing a local or other distillation module to match one or more pattern recognition criteria for a first destination context that are not used for a second destination context; and
implementing a compression protocol by
causing a leading qualifying connective trend to be distinguished from one or more other qualifying connective trends that match one or more pattern recognition criteria that are used for a first destination context; and
automatically causing justifications for using said leading qualifying connective trend in real time by differentiating said leading qualifying connective trend from another of said qualifying connective trends wherein said leading qualifying connective trend is said first connective trend.

5. The time series data distillation method of claim 1 comprising:
recognizing an outlier by one or more user-provided outlier recognition criteria of a state categorization protocol that include being a point that differs from a preceding point and from a next point in said time series by more than X % of a median magnitude of said other points in said time series wherein 1<X<20;
excluding said outlier from consideration when analyzing one or more trends in said time series wherein a second predictive outcome comprises one or more connective trend formulas or otherwise reflects a precise change rate;
using a value of an outlier category as a trigger for an automatic explanation protocol based on comparing a history against a timestamp of said outlier; and
presenting an explanatory label about said outlier that justifies said second connective trend.

6. The time series data distillation method of claim 1 wherein said first data state comprises a first accurate and precise point at a first time, wherein said second data state comprises a second accurate and precise point at a second time, and wherein said first connective trend spanning said first and second data states of said time series comprises a curvilinear model by which a precise prediction for a third time is obtained.

7. The time series data distillation method of claim 1 wherein a second predictive outcome is defined as one or more selected connective trends reflects an extrapolated scalar prediction partly based on a precise change rate and partly based on a time interval and wherein said second predictive outcome is presented contemporaneously with a precise digital expression of a risk of said second predictive outcome.

8. The time series data distillation method of claim 1 wherein a second predictive outcome is defined as one or more selected connective trends reflects an extrapolated scalar prediction partly based on an accurate and precise change rate and partly based on a time interval.

9. The time series data distillation method of claim 1 wherein a scalar digital historical expression has high accuracy insofar that it differs from a corresponding true value only by one or more rounding or correctable errors of said scalar digital expression.

10. The time series data distillation method of claim 1 comprising:
determining an expected range and automatically and conditionally notifying a user in a real time mode only a corresponding predicted value is outside said expected range.

11. The time series data distillation method of claim 1 wherein first and second predictive outcomes of said second connective trend reflect a precise change rate of a connective trend based on more than half of said states of said time series that are after said first data state.

12. The time series data distillation method of claim 1 wherein said first and second predictive outcomes reflect an accurate and precise extrapolated prediction based on more than half of said data states after said first data state.

13. The time series data distillation method of claim 1 comprising:
after causing a presentation of several sinusoidal, logarithmic, or other curved connective trends including a state prediction of each simultaneously with a label describing said connective trends to one or more users, receiving from said one or more users a different model type preference; and
responding to said different model type preference by causing a presentation of several linear connective trends including a state prediction of each simultaneously with a superseding label describing said several linear connective trends to said one or more users.

14. The time series data distillation method of claim 1 comprising:
associating said first and second data states with corresponding precise change rates; and
associating said first and second data states each with one or more network traffic states pertaining to a single network node.

15. A time series data distillation method comprising:
invoking transistor-based circuitry configured to obtain a time series comprising numerous data states including first, second, and third specific data states;
invoking transistor-based circuitry configured to obtain a first connective trend spanning said first and second data states of said time series and a corresponding first computed trend variability based on some or all of said numerous data states that are after said first data state of said numerous data states;
invoking transistor-based circuitry configured to obtain a second connective trend spanning said second and third data states of said time series and a corresponding second computed trend variability based on some or all of said numerous data states that are after said third data state of said numerous data states; and
invoking transistor-based circuitry configured to obtain a first user action after causing said first and second connective trends both to be presented to one or more users.

16. The time series data distillation method of claim 15 comprising:
implementing a first trending protocol by causing one or more trend patterns to be applied that match one or more criteria that are used selectively for transmitting an expression of said first connective trend to a first destination context but not for a second destination context;
implementing a second trending protocol by causing one or more trend patterns to be applied that match one or more criteria that are used selectively for transmitting an expression of said second connective trend to said second destination context but not for said first destination context; and
transmitting said first connective trend to said first destination context but not to said second destination context.

17. A time series data distillation computer program product comprising:
one or more tangible, nonvolatile storage media; and
machine instructions borne on said one or more tangible, nonvolatile storage media which, when running on one or more computer systems, cause said one or more computer systems to perform said method of claim 15.

18. A time series data distillation system comprising:
transistor-based circuitry configured to obtain a time series comprising numerous data states including first, second, and third specific data states;
transistor-based circuitry configured to obtain a first connective trend spanning said first and second data states of said time series and a corresponding first computed trend variability based on some or all of said numerous data states that are after said first data state of said numerous data states;
transistor-based circuitry configured to obtain a second connective trend spanning said second and third data states of said time series and a corresponding second computed trend variability based on some or all of said numerous data states that are after said third data state of said numerous data states; and
transistor-based circuitry configured to obtain a first user action after causing said first and second connective trends both to be presented to one or more users.
